(19) United States
(12) Patent Application Publication
(10) Pub. No.: US 2009/0263944 A1
(43) Pub. Date: Oct. 22, 2009

(54) Method for making low Vt gate-first light-reflective-layer covered dual metal-gates on high-k CMOSFETs

(76) Inventor: Albert Chin, LuJhou Township (TW)

Correspondence Address: BACON & THOMAS, PLLC, 625 SLATERS LANE, FOURTH FLOOR, ALEXANDRIA, VA, 22314-1176, US

(21) Appl. No.: 12/081,518

(22) Filed: Apr. 17, 2008

(51) Int. Cl. H01L 21/8238

(52) U.S. Cl. 438/199; 257/E27.108

(57) ABSTRACT

This invention proposes a method for making low Vₜ light-reflective-layer/dual-metal-gates/high-κ CMOSFETs with simple light-irradiation anneal and light-reflective-layer covered dual metal-gates with self-aligned and gate-first process compatible with current VLSI process. At 1.05 nm EOT, good φ_{m-eff} of 5.04 and 4.24 eV, low Vₜ of −0.16 and 0.13 V, high mobility of 85 and 209 cm²/Vs, and small 85° C. BTI≦40 mV (10 MV/cm, 1 hr) were measured for p- and n-MOSFETs. Using novel very high-κ TiLaO gate dielectric, low Vₜ of −0.07 and 0.12 V and high mobility of 82 and 203 cm²/Vs were achieved even at small EOT of 0.63 nm.

### BACKGROUND OF THE INVENTION

1. Field of the Invention

The invention relates to a method for making low threshold voltage (Vₜ) Gate-First Light-Reflective-Layer Covered Dual Metal-Gates on High-κ dielectric CMOSFETs Using Light-irradiation anneal. More particularly, the invention relates to a method for making low Vₜ Gate-First Dual Metal-Gates/High-κ CMOSFETs with laser or ultra-violate (UV) filtered Flash-light anneal.

2. Description of the Related Art

The toughest challenge for making metal-gate/high-κ CMOSFETs is to lower the undesired high Vₜ [1]*-[5]* (please refer to table 1 for detail prior arts [1]*-[6]*). Various high-κ dielectrics of Dy₂O₃/HfO₂, HfSiON, HfSi(Al)ON, HfLaON, and HfLaO with various dual metal gates for p/n MOSFETs of TaCₓN/TaCₓ, Ni₃1Si₁₂NiSi, TiAlN/TaSiN, Ni₃Si/NiSi₂, and Ir₃Si/TaN were used, but the Vₜ values are still high or can only demonstrated at larger equivalent-oxide thickness (EOT). This is especially hard for p-MOSFET, since only Ir and Pt in the Periodic Table have the needed high effective work-function (φ_{m-eff}) gate>5.2 eV [5]*. Previously the applicants showed the possible mechanism for high Vₜ related to the interface reaction and inter-diffusion of HfO₂ and Si-channel during high temperature rapid-thermal anneal (RTA) [6]*. Since these interface reactions follow basic chemistry of Arrhenius temperature dependence, the low temperature processing will be the solution. This was confirmed by the low |Vₜ|<0.1 V in HfLaO CMOSFETs using <900° C. solid-phase diffusion (SPD) formed ultra-shallow junction (USJ) [6]*. However, this SPD formed USJ is not compatible with current VLSI fabrication process. In this invention, the USJ is formed by VLSI-compatible conventional ion-implantation with light-irradiation anneal, but the challenge is to lower flat band voltage (V_{FB}) roll-off by high temperature under gate dielectric. A laser light anneal is used in the following to demonstrate the invention, although more general light-irradiation such as UV-filtered Flash-light anneal can also be used, but this invention is not intended to limit thereto.

FIG. 1 shows the sheet resistance (Rₛ) for 10 keV BF₂⁺ or As⁺ implanted Si after different laser annealing condition. For both BF₂⁺ and As⁺ implantation used for respective p- and n-MOSFETs, the Rₛ decreases rapidly with increasing laser fluence (energy/area) to 0.36 J/cm² and fast levels off. This is due to the melt of very thin Si (<50 nm) and re-crystallization. This is useful for next generation USJ, but the high laser energy is also absorbed by TaN-covered gate to cause unwanted V_{FB} roll-off shown in the capacitance-voltage (C-V) and V_{FB}-EOT plots of FIGS. 2˜3.

### SUMMARY OF THE INVENTION

To overcome the drawbacks of the prior arts, this invention proposes a method with simpler processes of ion implantation, light-irradiation anneal and light-reflective gate to achieve low Vₜ in metal-gate/high-κ CMOSFETs. At 1.05 nm EOT, the self-aligned and gate-first p- and n-MOSFETs of this invention showed proper effective work-function (φ_{m-eff}) of 5.04 and 4.24 eV, low Vₜ of −0.16 and 0.13 V, high mobility of 85 and 209 cm²/Vs and good 85° C. bias-temperature-instability (BTI) reliability. Using this novel very high-κ value TiLaO gate dielectric, desired low Vₜ of −0.07 and 0.12 V and high mobility of 82 and 203 cm²/Vs were achieved for respective p- and n-MOSFETs even at small EOT of 0.63 nm. This was realized using light-irradiation annealing on ion-implanted source-drain area and light-reflective Al-covered gate electrode. In this invention, Al reflects as high as 91% of the KrF excimer (248 nm wavelength) laser power irradiated to gate electrode as shown in the Reflectivity vs. light wavelength plot in FIG. 4: this lowers the temperature under the gate and decreases the high-κ/Si interface reaction exponentially. Since the reflectivity of Al is even slightly higher at longer wavelength than 248 nm, a UV-filtered Flash-light anneal is also able to achieve the similar annealing on ion-implanted damage in source-drain area but may reflect the light-irradiation absorption in Al-covered gate. Thus, the light-irradiation annealed/reflected low Vₜ CMOSFETs provide a simpler and lower cost process to prior art of Intel's CMOSFETs that use complicated gate dielectric first, poly-Si removal and filling gate electrode last process. These device data compare well with other reports in Table 1 [1]*-[6]*, with needed device integrity of low Vₜ, small EOT, self-aligned and gate-first process compatible with VLSI line.

TABLE 1
Comparison of device integrity data for various metal-gate/high-k n-
and p-MOSFETs.

| | | | | | | Mobility |
|---|---|---|---|---|---|---|
| | Metal-Gate, | | φm-eff | | | (cm²/Vs), |
| High-κ | p/n | EOT (nm) | (eV), p/n | Vₜ (V), p/n | Process | p/n |
| This invention | Al/TaN | 1.05 | 5.04/4.24 | −0.16/0.13 | Laser | 85/209 |
| HfLaON | covered | | | | Annealing/ | |
| | Ir₃Si/ | | | | Laser | |
| | HfSi₂₋ₓ | | | | Reflection | |
| This invention | Al/TaN | 0.63 | — | −0.07/0.12 | Laser | 83/203 |
| TiLaO | and | | | | Annealing/ | |
| | Al/TaN/Ir | | | | Laser | |
| | | | | | Reflection | |
| Dy₂O₃/HfO₂ [1]* | TaCₓNy/ | 1.4 | 4.9/4.2 | −0.36/0.23 | 1050° C. RTA | ~80/— |
| | TaCₓ | | | | | |
| HfSiON [2]* | Ni₃₁Si₁₂/ | 1.5 | ~4.8/~4.5 | −0.4/0.5 | Low Temp. | ~70/~240 |
| | NiSi | | | | FUSI | |
| HfSi(Al)ON [3]* | TiAlN/ | 1.0 | 4.8/4.44 | ~−0.5/~0.5 | 1000° C. RTA | ~50/~220 |
| | TaSiN | | | | | |
| HfSiON [4]* | Ni₃Si/ | 1.7 | 4.8/4.4 | −0.69/0.47 | Low Temp. | 65/230 |
| | NiSi₂ | | | | FUSI | |
| HfLaON [5]* | Ir₃Si/TaN | 1.6 | 5.08/4.28 | −0.1/0.18 | 1000° C. RTA | 84/217 |
| HfLaO [6]* | Ir/Hf | 1.2 | 5.3/4.1 | +0.05/0.03 | <900° C. SPD | 90/243 |

[1]* V. S. Chang et al, IEDM Tech. Dig., 2007, pp. 535-538.
[2]* T. Hoffmann et al, IEDM Tech. Dig., 2006, pp. 269-272.
[3]* M. Kadoshima et al, IEDM Tech. Dig., 2007, pp. 531-534.
[4]* K. Takahashi et al, IEDM Tech. Dig., 2004, pp. 91-94.
[5]* C. H. Wu et al, IEDM Tech. Dig., 2006, pp. 617-620.
[6]* C. F. Cheng et al, IEDM Tech. Dig., 2007, pp.333-336.

### BRIEF DESCRIPTION OF THE DRAWINGS

FIG. 1. Measured Rₛ of As⁺ and BF₂⁺ implantations at source-drain area after scanned KrF laser annealing. Sharp decrease of R₅ is obtained at 360 mJ/cm² fluence (energy/area).

FIG. 2. C-V characteristics of n- and p-MOS capacitors after laser annealing with and without top Al layer. The V_{FB} roll-off is found without using top Al on gate.

FIG. 3. V_{FB}-EOT plot of laser-annealed n and p-MOS capacitors with and without top Al layer. Much improved V_{FB} roll-off is reached using simple Al coverage on gate.

FIG. 4. Reflectivity (R) vs. light wavelength. High R of 91% are obtained for 100 nm thick Al but only 35% for TaN gate.

FIG. 5. J-V of Al/TaN/Ir₃Si/HfLaON and Al/TaN/HfSi₂₋ₓ/HfLaON p- & n-MOS devices after laser annealing and reflection at gate.

FIG. 6. Schematic diagram to show the laser reflection on Al-covered gate, during laser annealing on ion-implanted source-drain.

FIG. 7. Junction edge leakage current of laser annealing at 0.36 J/cm² and 1000° C. RTA.

FIG. 8. I_{d}-V_{d} of self-aligned & gate-first Al/TaN/[Ir₃Si—HfSi₂₋ₓ]/HfLaON p- and n-MOSFETs after laser annealing on source-drain and laser reflection at gate.

FIG. 9. I_{d}-V_{g} of self-aligned & gate-first Al/TaN/[Ir₃Si—HfSi₂₋ₓ]/HfLaON p- and n-MOSFETs after laser annealing on source-drain and laser reflection at gate.

FIG. 10. Hole and electron mobility of self-aligned and gate-first p- and n-MOSFETs after laser annealing on source-drain and laser reflection at gate.

FIG. 11. The ΔVₜ shift for laser-annealed Al/TaN/[Ir₃Si—HfSi₂₋ₓ]/HfLaON p- and n-MOSFETs stressed at 85° C. and 10 MV/cm for 1 hour.

FIG. 12. C-V characteristics of 0.63 nm EOT Al/TaN/TiLaO/p-Si and TaN/TiLaO/p-Si n-MOS capacitors after laser annealing with and without top Al layer, respectively. The V_{FB} roll-off is found without using top Al on gate.

FIG. 13. I_{d}-V_{d} of self-aligned & gate-first Al/TaN/Ir/TiLaO p-MOSFETs and Al/TaN/TiLaO n-MOSFETs after laser annealing/reflection with only 0.63 nm EOT.

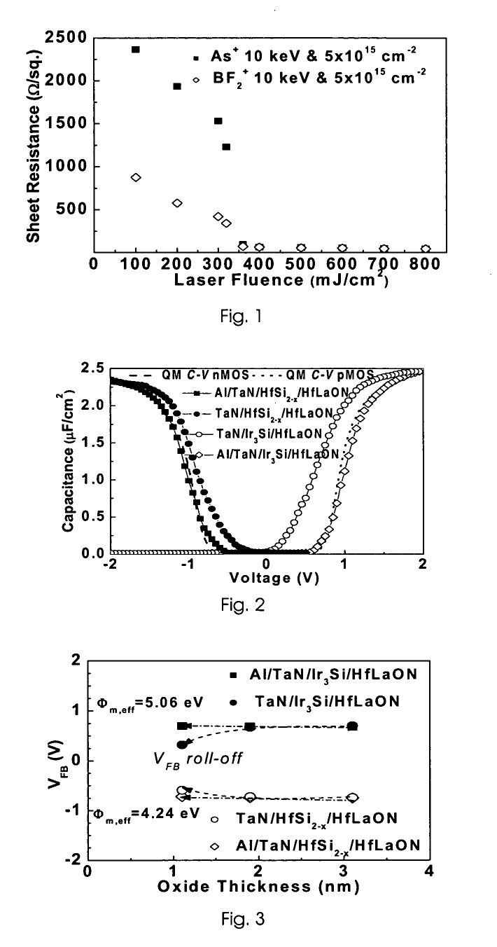

### DETAILED DESCRIPTION OF THE PREFERRED EMBODIMENT

For the best understanding of this invention, please refer to the following detailed description of the preferred embodiments and the accompanying drawings, wherein:

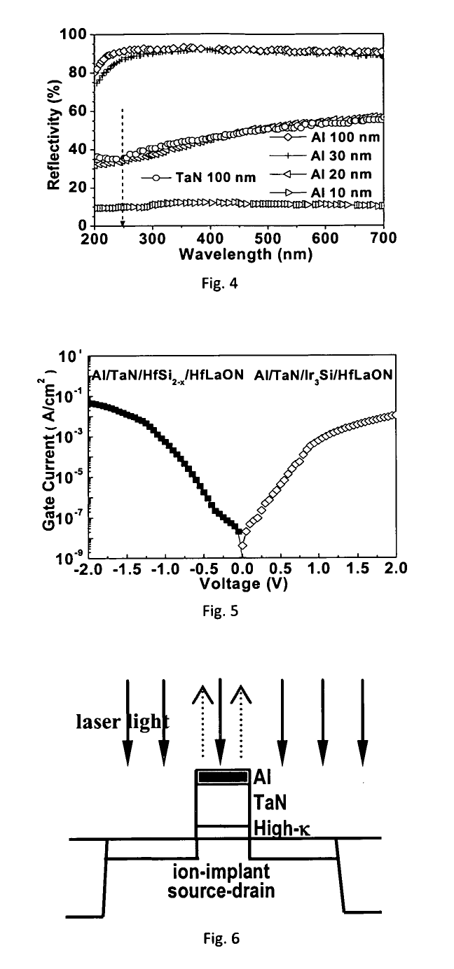

In view of the drawbacks of the prior arts, this invention proposes a method for making low Vₜ Gate-First light-reflective-layer/dual-metal-gates/high-κ CMOSFETs which added a thin light-reflection layer on top of dual metal-gates. FIG. 4 shows the optical reflectivity (R) vs. light wavelength. The R increases with Al layer thickness and reaches high R of 87% and 91% at 30 and 100 nm, even at short 248 nm KrF laser. It is important to notice that high R>90% is measured at longer UV wavelength to visible light wavelength. Therefore, this light-reflective method can also be used in Flash-light anneal method with additional UV-light filter. Using top Al laser-reflective gate, proper φ_{m-eff} of 5.04 and 4.24 eV are obtained with much improved V_{FB} roll-off compared with conventional top TaN gate (FIGS. 2-3). Owing to the low 660° C. melting temperature of Al, the laser energy should still be kept <0.55 J/cm². Alternatively, such higher energy-density light-irradiation caused device pattern distortion can be improved by using other high light-reflective layer such as Au, Ir, Pt, Cu, etc with higher melting temperature than Al. An EOT of 1.05 nm is obtained from quantum-mechanical C-V calculation in FIG. 2 with low leakage current of 6.7×10⁻⁴ and 5.4×10⁻⁴ A/cm² at ±1 V in FIG. 5. The φ_{m-eff} are the best reported data for CMOSFETs at ˜1.0 nm EOT; suggesting the low thermal budget under the gate is vitally important for metal-gate/high-κ CMOS. This is consistent with our previous very low Vₜ CMOSFETs using low temperature solid-phase diffused USJ [6]* and Intel's device with high-κ first and gate-electrode last process.

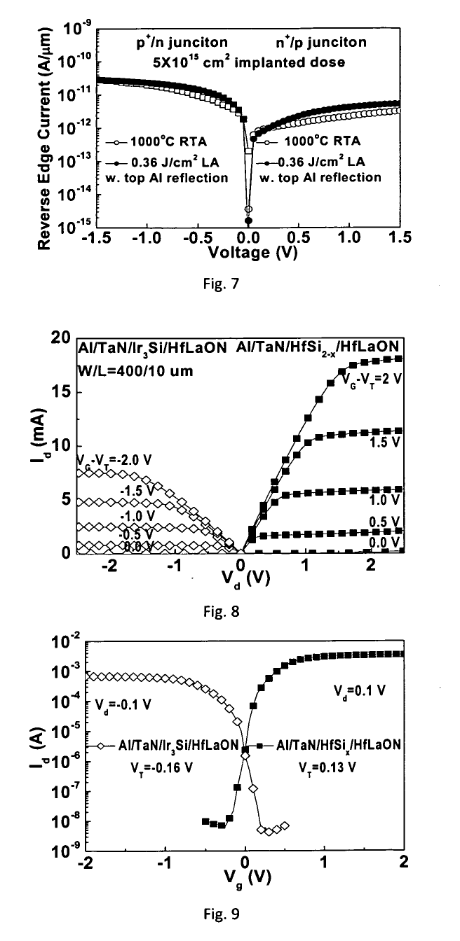

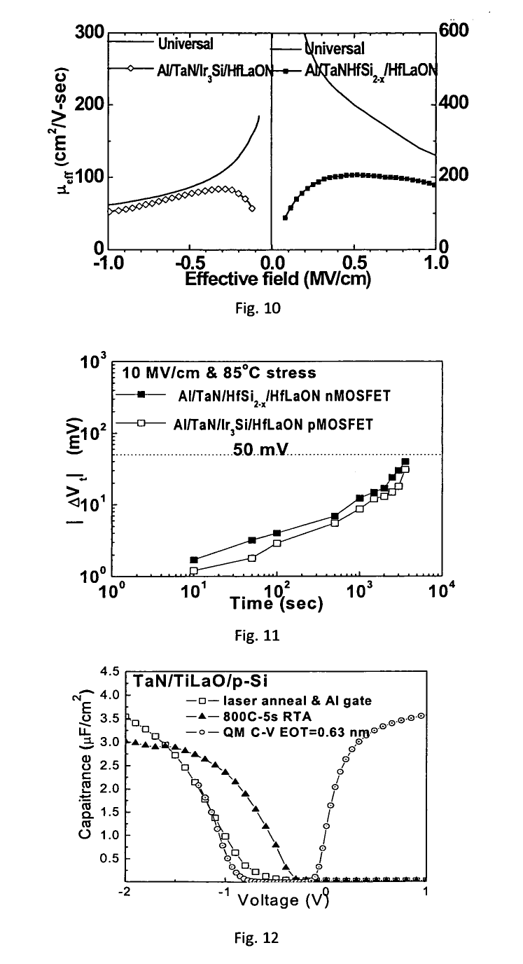

Using laser annealing on source-drain and laser reflection at gate in FIG. 6, good junction edge leakage comparable with 1000° C. RTA is obtained shown in FIG. 7. The drain current-drain voltage (I_{d}-V_{d}), drain current-gate voltage (I_{d}-V_{g}) and mobility-field (μ_{eff}-E) of CMOSFETs are shown in FIGS. 8-10. Besides good transistor characteristics, low Vₜ of −0.16 and 0.13 V and high mobility of 85 and 209 cm²/Vs are measured. The good reliability is shown in the BTI data of FIG. 11, where only small |ΔVₜ|≦40 mV occurs for CMOSFETs stressed at 10 MV/cm and 85° C. for 1 hr.

It is important to notice that the laser anneal/reflection process is the only art so far to scale the EOT down to 0.6 nm with proper Vₜ and V_{FB}, where such small EOT is needed and listed in International Technology Roadmap for Semiconductors (ITRS) for the 22 nm node technology. This is further shown in the C-V characteristics of the TaN/TiLaO/p-Si capacitor shown in FIG. 12. For the laser-annealed sample, additional light-reflective Al gate is added. The laser-annealed sample shows a small EOT of 0.63 nm and a proper V_{FB} of −0.78 V. In sharp contrast, the conventional RTA annealed sample shows both V_{FB} roll-off and EOT degradation. The degraded capacitance density is due to the interface reaction between high-κ gate dielectric and Si:

TiLaOₙ+Si→SiOₓ+TiLaOₙ₋ₓ (x<2) (1)

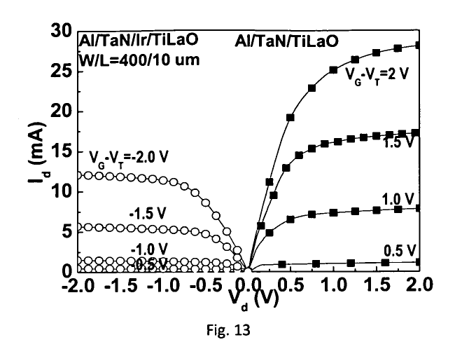

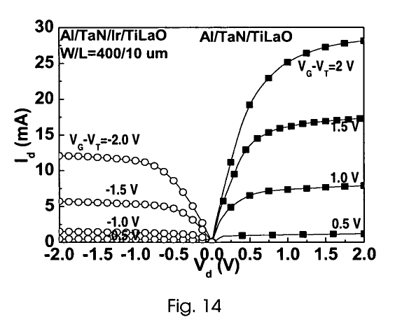

This is because of the smaller κ of SiO₂ (κ=3.9), which is significantly less than the TiLaO (κ˜50). Such reaction is possible due to the increasing bond enthalpy of 642, 799 and 800 kJ/mol for respective TiO₂, La₂O₃ and SiO₂. Such reaction is also possible for HfO₂-based high-κ dielectric even though the bond enthalpy is slightly increased to 802 kJ/mol. The formed oxygen vacancy in both SiOₓ and TiLaOₙ₋ₓ (x<2) also explains the undesired V_{FB} roll-off due to the charged dangling bands in the oxygen vacancy. FIG. 13 shows the I_{d}-V_{d} characteristics of the p- and n-MOSFETs. Good transistor behavior is measured even at small EOT of 0.63 nm. Table 1 compares various metal-gate/high-κ CMOSFETs data [1]*-[6]*. The merits of self-aligned and gate-first light-reflective Al-covered TaN/[Ir₃Si—HfSi₂₋ₓ]/HfLaON CMOSFETs with laser annealed shallow junction are small 1.05 nm EOT, proper φ_{m-eff} of 5.04 and 4.24 eV, low Vₜ of −0.16 and 0.13 V, high mobility of 85 and 209 cm²/Vs, and small BTI≦40 mV (85° C., 10 MV/cm & 1 hr). The Vₜ values are also lower than the reported 0.3˜0.4 V and −0.35˜−0.45 V V_{t,in} data of Intel's CMOSFETs using high-κ first and metal-gate last process. The light-reflective Al-covered [Ir/TaN—TaN]/TiLaO CMOSFETs show low Vₜ of −0.07 and 0.12 V, high mobility of 83 and 203 cm²/Vs at only 0.63 nm EOT. These results are comparable with or better than the best-reported data for self-aligned and gate-first metal-gate/high-κ CMOSFETs using simpler process.

Although a preferred embodiment of the invention has been described for purposes of illustration, it is understood that various changes and modifications to the described embodiment can be carried out without departing from the scope of the invention as disclosed in the appended claims.

1. A method for making low Vₜ gate-first light-reflective-layer/dual-metal-gates/high-k CMOSFETs, characterized by ⁻ using simple ion implantation doped source-drain, light-irradiation anneal and light-reflective top layer to achieve low Vₜ in high-k CMOSFETs.

2. The method for making low Vₜ gate-first light-reflective-layer/dual-metal-gates/high-k CMOSFETs according to claim 1, wherein light-irradiation anneal on ion-implanted source-drain and light-reflection by light-reflective-layer-covered gate electrode are employed.

3. The method for making low Vₜ gate-first light-reflective-layer/dual-metal-gates/high-k CMOSFETs according to claim 1, wherein small EOT in the range of 2˜0.5 nm, low |Vₜ|<0.3 V for n- and p-MOSFETs are achieved.

4. The method for making low Vₜ gate-first light-reflective-layer/dual-metal-gates/high-k CMOSFETs according to claim 1, wherein the light-irradiation is a kind of excimer laser or UV-light filtered Flash-light.

5. The method for making low Vₜ gate-first light-reflective-layer/dual-metal-gates/high-k CMOSFETs according to claim 2, wherein light-reflective-layer such as Al covered gate electrode reflects as high as 87%˜91% of the KrF excimer laser power.

6. The method for making low Vₜ gate-first light-reflective-layer/dual-metal-gates/high-k CMOSFETs according to claim 5, wherein the light-reflection mechanism lowers the temperature under the gate and decreases the high-k/Si interface reaction exponentially to achieve small EOT and low Vₜ.

7. The method for making low Vₜ gate-first light-reflective-layer/dual-metal-gates/high-k CMOSFETs according to claim 5, wherein other high light-reflectivity layer such as Au, Ir, Pt, Cu and their stacked or mixed layer can also be used to reflect the light-irradiation into gate electrode during light-irradiation anneal on ion-implanted source-drain.
